(19) United States
(12) Patent Application Publication
(10) Pub. No.: US 2025/0279916 A1
(43) Pub. Date: Sep. 4, 2025

(54) DEFERRED RESOLUTION FOR EQUALIZATION, DETECTION, AND SIGNAL RECONSTRUCTION

(71) Applicant: MaxLinear, Inc., Carlsbad, CA (US)

(72) Inventors: Curtis Ling, Carlsbad, CA (US); Sridhar Ramesh, Carlsbad, CA (US)

(73) Assignee: MaxLinear, Inc., Carlsbad, CA (US)

(21) Appl. No.: 19/067,744

(22) Filed: Feb. 28, 2025

Related U.S. Application Data
(60) Provisional application No. 63/560,471, filed on Mar. 1, 2024.

(51) Int. Cl. H04L 25/03; H03M 1/20

(52) U.S. Cl. CPC H04L 25/03057; H03M 1/208

(57) ABSTRACT

A method may include receiving, at a receiver, a signal including a symbol. The method may include performing, at the receiver in a first stage, a first operation to determine one or more most significant bits of the symbol. The method may include outputting, at the receiver, the one or more most significant bits when the one or more most significant bits falls within a hard resolution region.

### RELATED APPLICATION

This application claims the benefit of U.S. Provisional Application No. 63/560,471, filed Mar. 1, 2024, the disclosure of which is incorporated herein by reference in its entirety.

The examples discussed in the present disclosure are related to digital receivers and associated methods for equalization.

### BACKGROUND

Unless otherwise indicated herein, the materials described herein are not prior art to the claims in the present application and are not admitted to be prior art by inclusion in this section.

Digital communication systems map discrete symbols which may be modulated and transmitted as signals. The communication channel may impart noise, non-linear characteristics, and dispersion on the signal as the signal travels through the communication medium. The receiver may attempt to recover the signal embedded within the noise and other impairments. Methods for recovering the signal while balancing power constraints and performance constraints may be useful.

The subject matter claimed in the present disclosure is not limited to examples that solve any disadvantages or that operate only in environments such as those described above. Rather, this background is only provided to illustrate one example technology area where some examples described in the present disclosure may be practiced.

### SUMMARY

A method may include receiving, at a receiver, a signal including a symbol. The method may include performing, at the receiver in a first stage, a first operation to determine one or more most significant bits of the symbol. The method may include outputting, at the receiver, the one or more most significant bits when the one or more most significant bits falls within a hard resolution region.

A system for deferred resolution may include using the information obtained from symbols falling within a hard resolution region after the first processing operation to assist in resolving symbols not landing within that region following the first processing operation. Non-limiting examples of such assisted deferred resolution may include i) decision feedback equalization, ii) maximum likelihood sequence estimation, or the like.

A system for deferred resolution may include an analog to digital converter (ADC) stage, an equalizer, and a final ADC stage. The ADC stage may receive input, convert one or more most significant bits from the input, and generate an ADC residue from the input. The equalizer may include a plurality of taps in which the equalizer may receive the one or more most significant bits after conversion. The final ADC stage may provide one or more least significant bits to the equalizer when full resolution is selected.

A system may include an ADC, including a first stage that may convert, at the ADC, one or more most significant bits. The system may include a second stage that may delay, at the ADC, conversion of one or more least significant bits. The ADC may convert, in a second stage, one or more least significant bits when the one or more most significant bits falls within a full resolution region.

The objects and advantages of the examples will be realized and achieved at least by the elements, features, and combinations particularly pointed out in the claims.

Both the foregoing general description and the following detailed description are given as examples and are explanatory and are not restrictive of the invention, as claimed.

### BRIEF DESCRIPTION OF THE DRAWINGS

Examples will be described and explained with additional specificity and detail through the use of the accompanying drawings in which:

FIG. 1 illustrates example graphs for digital communication systems.

FIG. 2 illustrates example graphs for receiver signal processing.

FIG. 3 illustrates a block diagram of an example analog-digital converter.

FIG. 4A illustrates an example pipeline for deferred resolution.

FIG. 4B illustrates an example pipeline for deferred resolution.

FIG. 5 illustrates an example block diagram of a deferred resolution pipeline.

FIG. 6 illustrates an example block diagram of a deferred resolution pipeline.

FIG. 7 illustrates a block diagram of an example system for deferred resolution.

FIG. 8 illustrates an example process flow for deferred resolution.

FIG. 9 illustrates a diagrammatic representation of a machine in the example form of a computing device within which a set of instructions, for causing the machine to perform any one or more of the methods discussed herein, may be executed.

### DESCRIPTION

Receiver signal processing may involve equalization which may compensate for channel dispersion and other impairments. A digital transmitter may map a signal to transmitting symbols and transmit the signal over a communication medium. Reconstructing the signal may be performed by mapping the signal to the transmitted symbols.

Power usage may be excessive because of computations that may be omitted and/or skipped. Therefore, methods for reducing power usage while maintaining performance may be useful.

In one example, avoiding full resolution conversions may benefit one or more of power and/or effective number of bits. Deferred resolution may be combined with other power savings techniques such as deferred precision and/or deferred decision. Deferred resolution may be implemented using modified analog to digital converter (ADC) architecture.

In addition, information that is received by processing symbols falling within a hard resolution region may be used to resolve symbols that do not fall within the hard resolution region. For example, some use cases may include i) decision feedback equalization, ii) maximum likelihood sequence estimation, or the like. Some other use cases may include belief propagation and/or low density parity check (LDPC) coding. In these cases, partial information (e.g., information obtained that falls within a hard resolution region) may be used to determine information that does not fall within a hard resolution region. Alternatively or in addition, information that falls within a hard resolution region may be used without determining information that does not fall within a hard resolution region. Omitting operations that do not fall within a hard resolution region may reduce processing power relative to a baseline.

Deferred resolution may be applied to numerous techniques beyond equalization, detection, and signal reconstruction. For example, deferred resolution may be used in classification, decoding, and quantization. In the case of classification of images and/or videos, a first pass on a low resolution image may be facilitated (e.g., the base layers with layered encoding). A conditional second pass may be facilitated if the first pass classification is not successful. In the case of decoding, iterative decoding with early termination may be provided. For example decoding may use a low density parity check decoder or a Viterbi decoder. In the case of quantization of signals/voltages, a first pass of the signals/voltages may be facilitated and then a conditional second pass may be provided if the first-pass is not successful.

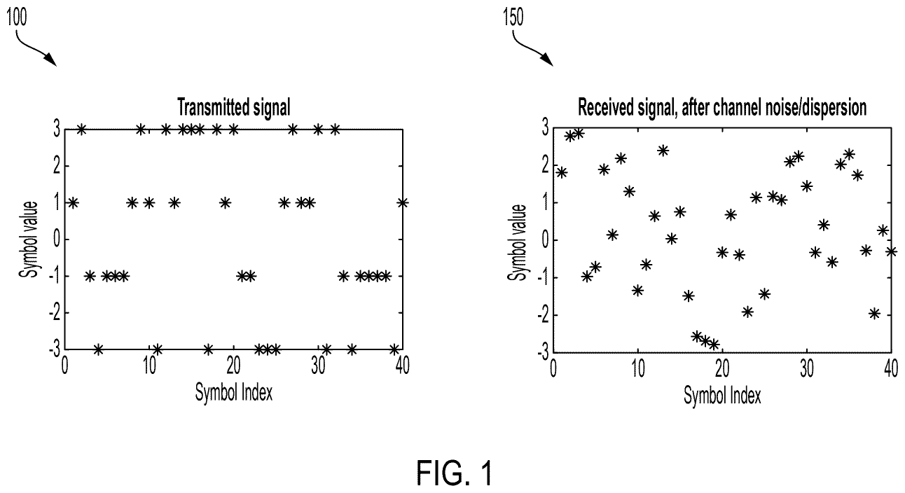

FIG. 1 illustrates example graphs for digital communication systems. Information may be mapped to discrete “symbols”, then modulated and transmitted as a signal. A graph 100 of the transmitted signal has a symbol index (e.g., ranging from 0 to 40) that is mapped to a symbol value (e.g., having a symbol value of −3, or −1, or 1, or 3). The communication channel may impart noise, non-linearity, and/or dispersion on the signal. A graph 150 of the received signal after channel noise and/or dispersion shows a symbol index (e.g., ranging from 0 to 40) and a symbol value (e.g., having a symbol value ranging between −3 and 3). The four discrete symbol values of the graph 100 have been replaced by additional values in the graph 150. The receiver may attempt to recover the signal embedded within noise and other impairments, e.g., using Pulse Amplitude Modulation in intensity modulation direct detection (IMDD)-optical communication systems.

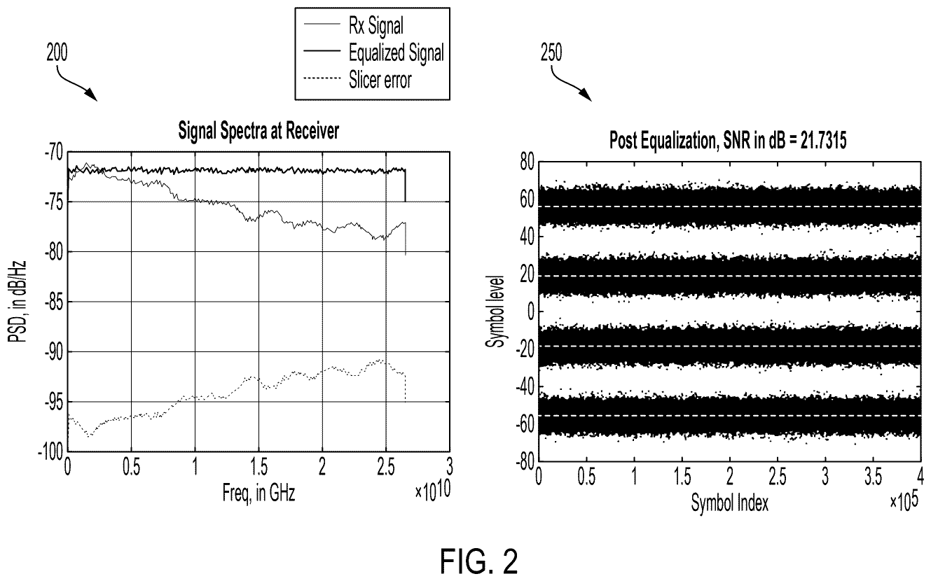

FIG. 2 illustrates example graphs 200, 250 for receiver signal processing. Equalization may compensate for channel dispersion. In graph 200, the power spectral density (PSD) in decibels per hertz (dB/Hz) is plotted against the frequency in gigahertz (GHz) to show the signal spectra at the receiver of various signals and errors. In graph 200, a received (Rx) signal is shown, an equalized signal is shown, and a slicer error is shown. In graph 250, the symbol level is plotted as a function of the symbol index in a post equalization graph in which the signal-to-noise ratio (SNR) in dB is 21.7315. Detection may be used to map the signal to the transmitted symbols. This may be accomplished using a simple slicer (e.g., using the minimum distance to nominal symbol level) or Maximum Likelihood Sequence Detection on un-equalized or partially equalized signals.

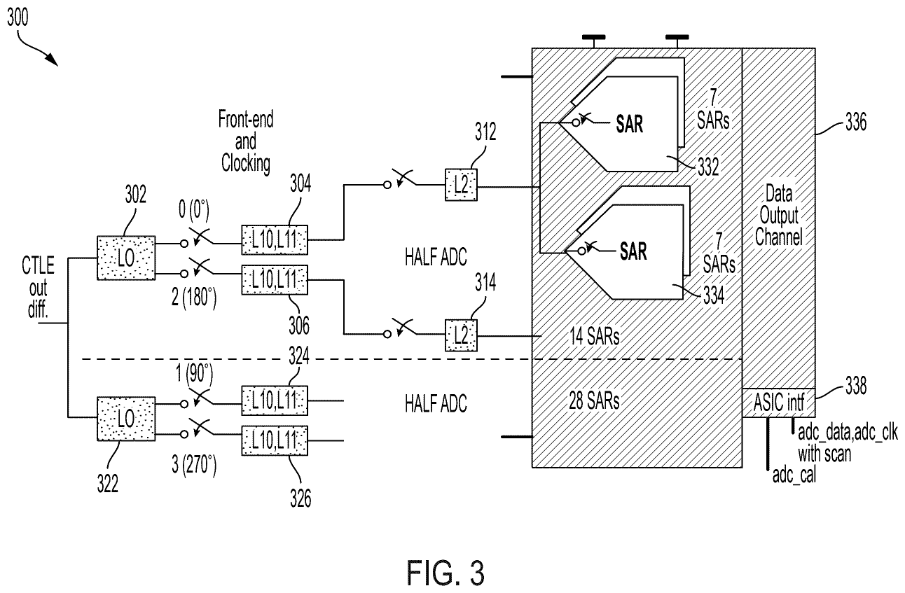

FIG. 3 illustrates an example block diagram for ADC 300. A continuous time linear equalizer (CTLE) output differential may be input to L0 302 or L0 322 at a front end and clocking region. At L0 302, the signal may be directed to a switch that closes at 0° and a switch that closes at 180°. When the signal is directed past the switch that closes at 0°, the signal may be directed to L10, L11 304. The signal may be further directed past another switch to L2 312 at a half ADC before being input to a successive approximation register (SAR) 332 and SAR 334. When the signal is directed past the switch that closes at 180°, the signal may be directed to L10, L11 306. The signal may be further directed past another switch to L2 314 at a half ADC before being input to successive approximation registers.

At L0 322, the signal may be directed to a switch that closes at 90° and a switch that closes at 270°. When the signal is directed past the switch that closes at 90°, the signal may be directed to L10, L11 324. The signal may be further directed to SARs. When the signal is directed past the switch that closes at 270°, the signal may be directed to L10, L11 326 and further directed to a half ADC. The signal may be further directed past the half-ADC to SARs.

The SARs (e.g., SAR 332, SAR 334) may be coupled to a data output channel 336. The data output channel 336 may interface with an application specific integrated circuit (ASIC) interface 338. The ASIC interface may interface with various components including analog-to-digital converter calibration (adc_cal), analog-to-digital converter data (adc_data), and analog-to-digital converter clock (adc_clk) with scan.

During an ADC conversion, there may not be an immediate use for full precision. Therefore, a pipelined ADC may be structured to produce X_{M} (e.g., most significant bits) in first stage(s), with other stage(s) producing X_{L} (e.g., least significant bits). In an ADC without pipelining, as illustrated in FIG. 3, the ADC may be modified for successive approximation register (SAR) (e.g. split into 2 stages).

In some examples, an ADC may include a first stage that may convert, at the ADC, one or more most significant bits; and a second stage that may delay, at the ADC, conversion of one or more least significant bits. The one or more least significant bits may be converted, at the ADC in a second stage, when the one or more most significant bits fall within a full resolution region. The ADC may further include a prediction engine that may compute a conversion decision for the one or more least significant bits. The ADC may further include a prediction engine that may compute a second conversion decision based on a first conversion result. The ADC may stop a conversion of the one or more least significant bits in one or more adjacent slices. The ADC may determine one or more thresholds for full resolution.

While the equalizer (e.g., FFE) is processing X_{M}(n) (e.g., most significant bits), the residue (e.g., the remaining bits without the most significant bits) may move to an analog delay stage. The ADC may convert X_{L}(n) (e.g., the least significant bits) when the equalizer's computation of the most significant bits (e.g., FFE(X_{M}(n)) falls outside of a hard decision region. When the equalizer's computation of the most significant bits (e.g., FFE(X_{M})) falls within a hard decision region, the analog to digital conversion of the least significant bits (e.g., X_{L}(n) conversion) may be omitted. Otherwise, when the equalizer's computation of the most significant bits (e.g., FFE(X_{M})) falls outside the hard decision region, the analog to digital conversion of the least significant bits (e.g., X_{L}(n) conversion) may be performed. The equalizer's computation of the most significant bits (e.g., FFE(X_{M})) and an equalizer's computation of the least significant bits (e.g., FFE(X_{L})) may be combined and resliced.

In some examples (e.g., for the case of ADC calibration, using clock recovery unit (CRU) and/or least mean square (LMS)), full resolution may be used on a subset of symbols. That is, ADC calibration and CRU may operate on a known subset of symbols which may default to full precision. CRU may include 18/56 of the conversions, while ADC calibration input may be down-sampled 16×. Therefore, full resolution may be used 39% of the time. For the other 61% of samples, deferred resolution may be used.

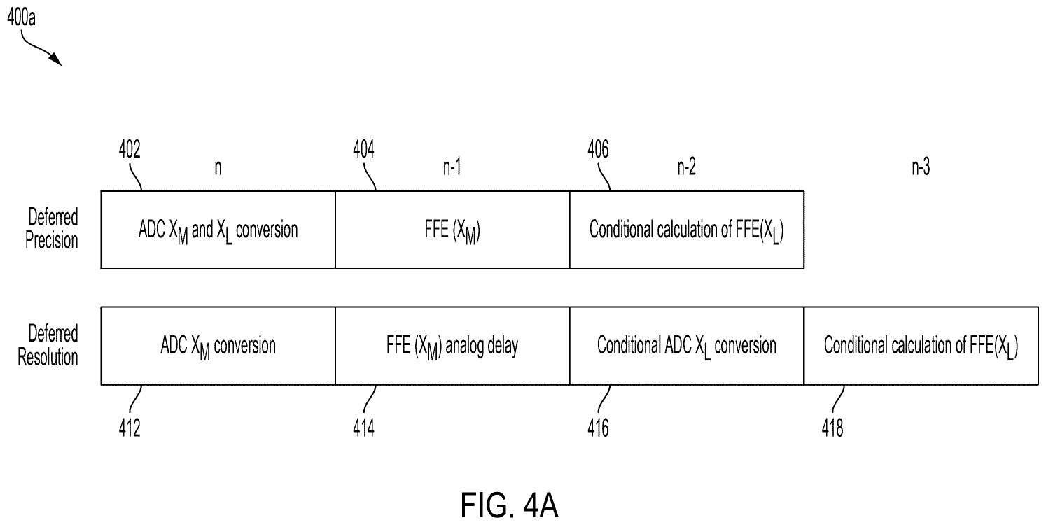

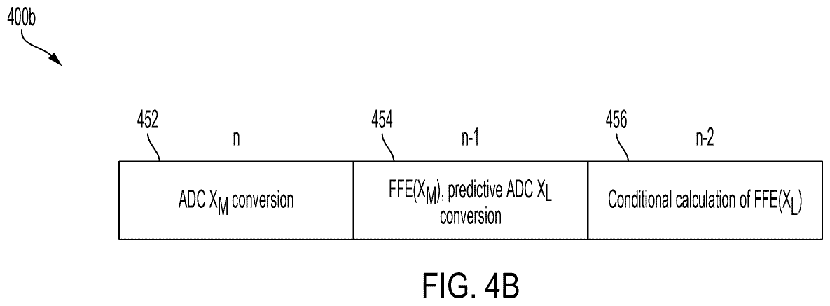

As illustrated in the diagram 400a in FIG. 4A, a method for deferred resolution may include: receiving, at a receiver, a signal including a symbol; performing, at the receiver in a first stage, a first operation to determine one or more most significant bits of the symbol; and outputting, at the receiver, the one or more most significant bits when the one or more most significant bits falls within a hard resolution region. The first operation may be an equalization operation that may use an FFE.

The method may include converting, at the receiver in a second stage, one or more least significant bits when the one or more most significant bits falls within a full resolution region; and combining, at the receiver, the one or more least significant bits with the one or more most significant bits when the one or more most significant bits falls within a full resolution region.

The method may include stopping, at the receiver, a conversion of one or more least significant bits in one or more adjacent slices. The method may include performing, at the receiver, an analog delay before converting one or more least significant bits.

For deferred resolution, X_{M} and X_{L} may have more time to convert which may provide reduced power and increases in performance related to effective number of bits (ENOB).

Deferred precision may be compared to deferred resolution. Deferred precision may include analog to digital conversion of X_{M} and X_{L} at time n, as shown in operation 402. Deferred resolution may similarly include analog to digital conversion of X_{M} at time n, as shown in operation 412. At time (n-1), the equalizer's computation of the most significant bits (e.g., FFE(X_{M})) may be performed, as shown by operation 404. During this time (n-1), for deferred resolution, there may be the computation (e.g., using an equalizer) of the most significant bits (e.g., FFE X_{M})) and an analog delay operation, as shown in operation 414. At time (n-2), deferred resolution may include a conditional conversion of the least significant bits (e.g., conditional ADC X_{L} conversion), as shown by operation 416. Deferred precision may not include this operation at time (n-2). Deferred precision may include conditional calculation of FFE(X_{L}) during time (n-2), as shown by operation 406. Deferred resolution may also include conditional calculation of FFE(X_{L}); however, the time may be at (n-3), not (n-2), as shown by operation 418.

As illustrated in FIG. 4B, a prediction engine may be used to compute a first conversion result (e.g., FFE(X_{M})). The prediction engine may use the first conversion result (e.g., FFE(X_{M})) to make a second conversion decision (e.g., a decision to compute FFE(X_{L})).

When using a prediction engine, un-equalized value X_{M}(n) plus prior equalized and un-equalized values X_{M}(n-1), X_{M}(n-2), and the like may be used without waiting for FFE(X_{M}) to compute. Using X_{M}(n) and with FFE(X_{M}(n-1)) already calculated, the prediction engine may make a prediction as to whether FFE(X_{M}(n)) will land in a deferred decision region. The penalty for a bad guess may be low and the payoff may be the omission of the analog delay stage.

As shown in the diagram 400b in FIG. 4B, a conditional calculation of FFE (X_{L}) may be computed at time (n-2), as shown in operation 456. As shown in operation 454, at time (n-1), FFE(X_{M}) may be computed and a predictive ADC X_{L} conversion may be computed using the prediction engine. As shown in operation 452, at time (n), ADC X_{M} conversion may be computed.

Alternatively or in addition, the prediction engine and/or the analog delay may be avoided by omitting and/or skipping the conversion of X_{L} in the adjacent slice(s). This omission and/or skipping may provide time to compute FFE(X_{M}) to determine the decision region. One slice may be used when an adequate time to determine the decision region is provided; otherwise, more than once slice (e.g., 2 slices) may be used to provide an adequate time to determine the decision region. The reduced precision of X_{M} may reduce the time used to compute FFE(X_{M}) and make a decision. The decision may be passed on to the slices except for the adjacent slice(s) in order to avoid fully converting X_{L}. The overhead of this approach may be low (e.g., 1/N_{slices}, or less than 2% for a 56-slice ADC per sacrificed slice). If additional time is to be used to compute FFE(X_{M}), then more slices may be omitted and/or skipped. The time to compute FFE(X_{M}) may be further decreased by reducing the number of taps included in the calculation, trading off against accuracy.

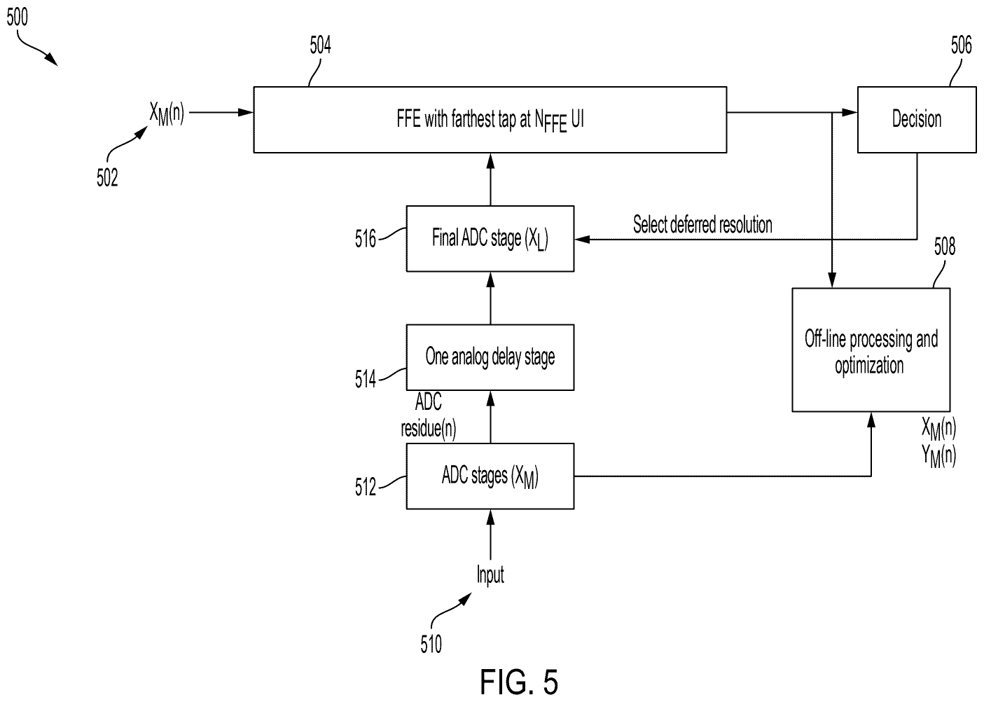

As illustrated in FIG. 5, a system 500 for deferred resolution may include an analog to digital converter (ADC) stage 512 that may receive input 510, convert one or more most significant bits (e.g., X_{M}) from the input 510, and generate an ADC residue (n) from the input 510. The system may include an equalizer 504 including taps (e.g., FFE with farthest tap at N_{FFE}UI). The equalizer 504 may receive the one or more most significant bits 502 (e.g., X_{M}(n)) after conversion. The system 500 may include a final ADC stage 516 that may provide one or more least significant bits (e.g., X_{L}) to the equalizer when full resolution is selected. When deferred resolution is selected, the system may prevent the one or more least significant bits (e.g., X_{L}) from passing to the equalizer. The equalizer may be an FFE.

The system may include an analog delay stage 514 that may delay a conversion of the one or more least significant bits. The equalizer may equalize the one or more least significant bits when full resolution is selected based on a decision 506. Off-line processing and optimization may use the decision 506 and the ADC stages 512. The equalizer may stop a conversion of one or more least significant bits in one or more adjacent slices. The system may include one or more processors that may determine one or more thresholds for full resolution. Off-line processing and optimization 508 may use the decision 506 and the signals X_{M}(n) and Y_{M} (n) for various computations.

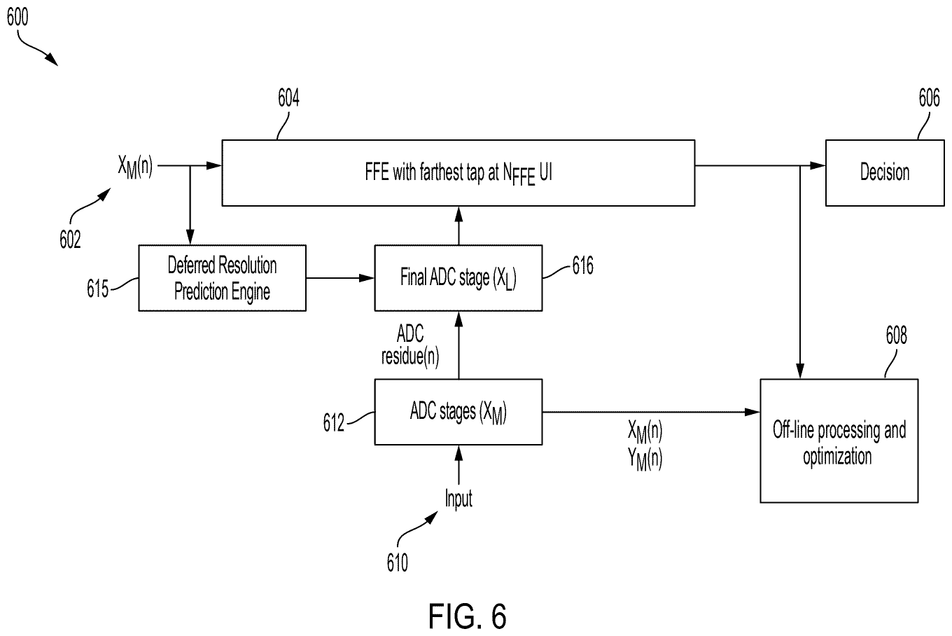

As illustrated in FIG. 6, a prediction engine may be used. The system 600 may include a deferred resolution prediction engine 615. The deferred resolution prediction engine 615 may determine a second conversion decision based on a first conversion result. The prediction engine may be used to train an algorithm to determine the likelihood of a deferred decision. Instead of waiting for X_{M} to compute, based on the prediction, a conversion decision may be determined. When the prediction engine is used, the analog delay stage may be skipped or omitted.

Input 610 may be provided to ADC Stages (X_{M}) 612. An ADC residue (n) may be generated and X_{M}(n) and Y_{M}(n) may be sent for off-line processing and optimization 608. A final ADC stage (X_{L}) 616 may be performed. Using the deferred resolution prediction engine 615, the final ADC stage (X_{L}) 616 may determine whether the least significant bits may be equalized using equalizer 604. The equalizer 604 may equalize the most significant bits X_{M}(n) 602 without relying on a deferred resolution prediction engine 615. The output from the equalizer 604 may be used in a decision 606. The decision 606 may not feedback to a final ADC stage (X_{L}) 616. Off-line processing and optimization 608 may use the decision 606 and the signals X_{M}(n) and Y_{M}(n) for various computations.

In addition to use cases involving equalization and ADCs, deferred resolution may be implemented in decision feedback equalization, ii) maximum likelihood sequence estimation, (iii) belief propagation and/or (iv) low density parity check (LDPC) coding. In these cases, information that falls within a hard resolution region may be used to determine information that falls within a deferred resolution region. In some cases, the partial information obtained from determining information that falls within a hard resolution region may be adequate for the particular use case. As a result, the amount of processing may be reduced relative to a baseline and the performance (e.g., effective number of bits) may be maintained.

In some cases, deferred resolution may be applied independently of deferred precision. In other cases, deferred resolution may be applied in conjunction with deferred precision.

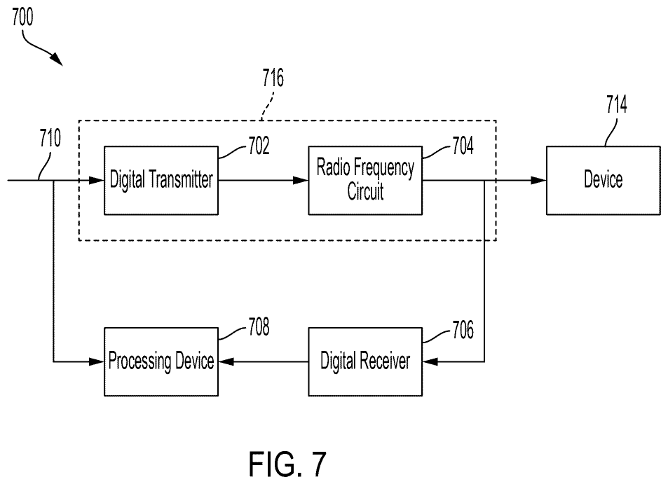

FIG. 7 illustrates a block diagram of an example communication system 700 configured for deferred resolution, in accordance with at least one example described in the present disclosure. The communication system 700 may include a digital transmitter 702, a radio frequency circuit 704, a device 714, a digital receiver 706, and a processing device 708. The digital transmitter 702 and the processing device may be configured to receive a baseband signal via connection 710. A transceiver 716 may comprise the digital transmitter 702 and the radio frequency circuit 704.

In some examples, the communication system 700 may include a system of devices that may be configured to communicate with one another via a wired or wireline connection. For example, a wired connection in the communication system 700 may include one or more Ethernet cables, one or more fiber-optic cables, and/or other similar wired communication mediums. Alternatively, or additionally, the communication system 700 may include a system of devices that may be configured to communicate via one or more wireless connections. For example, the communication system 700 may include one or more devices configured to transmit and/or receive radio waves, microwaves, ultrasonic waves, optical waves, electromagnetic induction, and/or similar wireless communications. Alternatively, or additionally, the communication system 700 may include combinations of wireless and/or wired connections. In these and other examples, the communication system 700 may include one or more devices that may be configured to obtain a baseband signal, perform one or more operations to the baseband signal to generate a modified baseband signal, and transmit the modified baseband signal, such as to one or more loads.

In some examples, the communication system 700 may include one or more communication channels that may communicatively couple systems and/or devices included in the communication system 700. For example, the transceiver 716 may be communicatively coupled to the device 714.

In some examples, the transceiver 716 may be configured to obtain a baseband signal. For example, as described herein, the transceiver 716 may be configured to generate a baseband signal and/or receive a baseband signal from another device. In some examples, the transceiver 716 may be configured to transmit the baseband signal. For example, upon obtaining the baseband signal, the transceiver 716 may be configured to transmit the baseband signal to a separate device, such as the device 714. Alternatively, or additionally, the transceiver 716 may be configured to modify, condition, and/or transform the baseband signal in advance of transmitting the baseband signal. For example, the transceiver 716 may include a quadrature up-converter and/or a digital to analog converter (DAC) that may be configured to modify the baseband signal. Alternatively, or additionally, the transceiver 716 may include a direct radio frequency (RF) sampling converter that may be configured to modify the baseband signal.

In some examples, the digital transmitter 702 may be configured to obtain a baseband signal via connection 710. In some examples, the digital transmitter 702 may be configured to up-convert the baseband signal. For example, the digital transmitter 702 may include a quadrature up-converter to apply to the baseband signal. In some examples, the digital transmitter 702 may include an integrated digital to analog converter (DAC). The DAC may convert the baseband signal to an analog signal, or a continuous time signal. In some examples, the DAC architecture may include a direct RF sampling DAC. In some examples, the DAC may be a separate element from the digital transmitter 702.

In some examples, the transceiver 716 may include one or more subcomponents that may be used in preparing the baseband signal and/or transmitting the baseband signal. For example, the transceiver 716 may include an RF front end (e.g., in a wireless environment) which may include a power amplifier (PA), a digital transmitter (e.g., 702), a digital front end, an Institute of Electrical and Electronics Engineers (IEEE) 1588v2 device, a Long-Term Evolution (LTE) physical layer (L-PHY), an (S-plane) device, a management plane (M-plane) device, an Ethernet media access control (MAC)/personal communications service (PCS), a resource controller/scheduler, and the like. In some examples, a radio (e.g., a radio frequency circuit 704) of the transceiver 716 may be synchronized with the resource controller via the S-plane device, which may contribute to high-accuracy timing with respect to a reference clock.

In some examples, the transceiver 716 may be configured to obtain the baseband signal for transmission. For example, the transceiver 716 may receive the baseband signal from a separate device, such as a signal generator. For example, the baseband signal may come from a transducer configured to convert a variable into an electrical signal, such as an audio signal output of a microphone picking up a speaker's voice. Alternatively, or additionally, the transceiver 716 may be configured to generate a baseband signal for transmission. In these and other examples, the transceiver 716 may be configured to transmit the baseband signal to another device, such as the device 714.

In some examples, the transceiver 716 may be configured to receive a transmission from the transceiver 716. For example, the transceiver 716 may be configured to transmit a baseband signal to the device 714.

In some examples, the radio frequency circuit 704 may be configured to transmit the digital signal received from the digital transmitter 702. In some examples, the radio frequency circuit 704 may be configured to transmit the digital signal to the device 714 and/or the digital receiver 706. In some examples, the digital receiver 706 may be configured to receive a digital signal from the RF circuit and/or send a digital signal to the processing device 708.

In some examples, the processing device 708 may be a standalone device or system, as illustrated. Alternatively, or additionally, the processing device 708 may be a component of another device and/or system. For example, in some examples, the processing device 708 may be included in the transceiver 716. In instances in which the processing device 708 is a standalone device or system, the processing device 708 may be configured to communicate with additional devices and/or systems remote from the processing device 708, such as the transceiver 716 and/or the device 714. For example, the processing device 708 may be configured to send and/or receive transmissions from the transceiver 716 and/or the device 714. In some examples, the processing device 708 may be combined with other elements of the communication system 700.

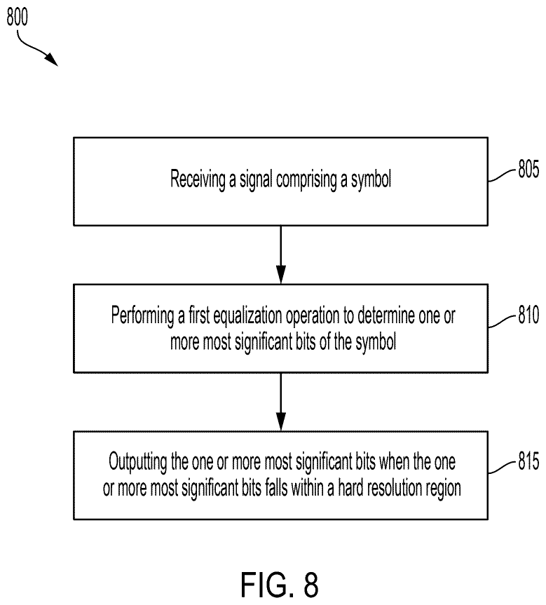

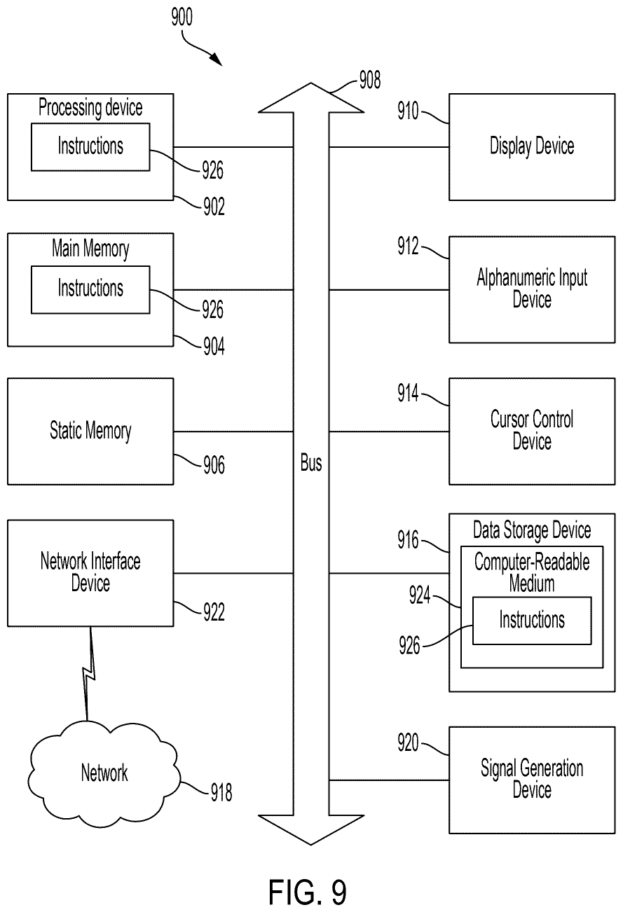

FIG. 8 illustrates a process flow of an example method 800 of deferred resolution, in accordance with at least one example described in the present disclosure. The method 800 may be arranged in accordance with at least one example described in the present disclosure. The method 800 may be performed by processing logic that may include hardware (circuitry, dedicated logic, etc.), software (such as is run on a computer system or a dedicated machine), or a combination of both, which processing logic may be included in the processor (e.g., the processing device 902 of FIG. 9), the communication system 700 of FIG. 7, or another device, combination of devices, or systems.

The method 800 may begin at block 805 where the processing logic receive, at a receiver, a signal comprising a symbol. At block 810, the processing logic may perform, at the receiver in a first stage, a first equalization operation to determine one or more most significant bits of the symbol. At block 815, the processing logic may output, at the receiver, the one or more most significant bits when the one or more most significant bits falls within a hard resolution region.

Modifications, additions, or omissions may be made to the method 800 without departing from the scope of the present disclosure. For example, in some examples, the method 800 may include any number of other components that may not be explicitly illustrated or described.

For simplicity of explanation, methods and/or process flows described herein are depicted and described as a series of acts. However, acts in accordance with this disclosure may occur in various orders and/or concurrently, and with other acts not presented and described herein. Further, not all illustrated acts may be used to implement the methods in accordance with the disclosed subject matter. In addition, those skilled in the art will understand and appreciate that the methods may alternatively be represented as a series of interrelated states via a state diagram or events. Additionally, the methods disclosed in this specification are capable of being stored on an article of manufacture, such as a non-transitory computer-readable medium, to facilitate transporting and transferring such methods to computing devices. The term article of manufacture, as used herein, is intended to encompass a computer program accessible from any computer-readable device or storage media. Although illustrated as discrete blocks, various blocks may be divided into additional blocks, combined into fewer blocks, or eliminated, depending on the desired implementation.

FIG. 9 illustrates a diagrammatic representation of a machine in the example form of a computing device 900 within which a set of instructions, for causing the machine to perform any one or more of the methods discussed herein, may be executed. The computing device 900 may include a rackmount server, a router computer, a server computer, a mainframe computer, a laptop computer, a tablet computer, a desktop computer, or any computing device with at least one processor, etc., within which a set of instructions, for causing the machine to perform any one or more of the methods discussed herein, may be executed. In alternative examples, the machine may be connected (e.g., networked) to other machines in a local area network (LAN), an intranet, an extranet, or the Internet. The machine may operate in the capacity of a server machine in client-server network environment. Further, while only a single machine is illustrated, the term “machine” may also include any collection of machines that individually or jointly execute a set (or multiple sets) of instructions to perform any one or more of the methods discussed herein.

The example computing device 900 includes a processing device 902, a main memory 904 (e.g., read-only memory (ROM), flash memory, dynamic random access memory (DRAM) such as synchronous DRAM (SDRAM)), a static memory 906 (e.g., flash memory, static random access memory (SRAM)) and a data storage device 916, which communicate with each other via a bus 908.

Processing device 902 represents one or more general-purpose processing devices such as a microprocessor, central processing unit, or the like. More particularly, the processing device 902 may include a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device 902 may also include one or more special-purpose processing devices such as an application specific integrated circuit (ASIC), a field programmable gate array (FPGA), a digital signal processor (DSP), network processor, or the like. The processing device 902 is configured to execute instructions 926 for performing the operations and steps discussed herein.

The computing device 900 may further include a network interface device 922 which may communicate with a network 918. The computing device 900 also may include a display device 910 (e.g., a liquid crystal display (LCD) or a cathode ray tube (CRT)), an alphanumeric input device 912 (e.g., a keyboard), a cursor control device 914 (e.g., a mouse) and a signal generation device 920 (e.g., a speaker). In at least one example, the display device 910, the alphanumeric input device 912, and the cursor control device 914 may be combined into a single component or device (e.g., an LCD touch screen).

The data storage device 916 may include a computer-readable storage medium 924 on which is stored one or more sets of instructions 926 embodying any one or more of the methods or functions described herein. The instructions 926 may also reside, completely or at least partially, within the main memory 904 and/or within the processing device 902 during execution thereof by the computing device 900, the main memory 904 and the processing device 902 also constituting computer-readable media. The instructions may further be transmitted or received over a network 918 via the network interface device 922.

While the computer-readable storage medium 924 is shown in an example to be a single medium, the term “computer-readable storage medium” may include a single medium or multiple media (e.g., a centralized or distributed database and/or associated caches and servers) that store the one or more sets of instructions. The term “computer-readable storage medium” may also include any medium that is capable of storing, encoding or carrying a set of instructions for execution by the machine and that cause the machine to perform any one or more of the methods of the present disclosure. The term “computer-readable storage medium” may accordingly be taken to include, but not be limited to, solid-state memories, optical media and magnetic media.

In some examples, the different components, modules, engines, and services described herein may be implemented as objects or processes that execute on a computing system (e.g., as separate threads). While some of the systems and methods described herein are generally described as being implemented in software (stored on and/or executed by hardware), specific hardware implementations or a combination of software and specific hardware implementations are also possible and contemplated.

Terms used herein and especially in the appended claims (e.g., bodies of the appended claims) are generally intended as “open” terms (e.g., the term “including” should be interpreted as “including, but not limited to,” the term “having” should be interpreted as “having at least,” the term “includes” should be interpreted as “includes, but is not limited to,” etc.).

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations.

In addition, even if a specific number of an introduced claim recitation is explicitly recited, it is understood that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” or “one or more of A, B, and C, etc.” is used, in general such a construction is intended to include A alone, B alone, C alone, A and B together, A and C together, B and C together, or A, B, and C together, etc. For example, the use of the term “and/or” is intended to be construed in this manner.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

Additionally, the use of the terms “first,” “second,” “third,” etc., are not necessarily used herein to connote a specific order or number of elements. Generally, the terms “first,” “second,” “third,” etc., are used to distinguish between different elements as generic identifiers. Absence a showing that the terms “first,” “second,” “third,” etc., connote a specific order, these terms should not be understood to connote a specific order. Furthermore, absence a showing that the terms first,” “second,” “third,” etc., connote a specific number of elements, these terms should not be understood to connote a specific number of elements. For example, a first widget may be described as having a first side and a second widget may be described as having a second side. The use of the term “second side” with respect to the second widget may be to distinguish such side of the second widget from the “first side” of the first widget and not to connote that the second widget has two sides.

All examples and conditional language recited herein are intended for pedagogical objects to aid the reader in understanding the invention and the concepts contributed by the inventor to furthering the art, and are to be construed as being without limitation to such specifically recited examples and conditions. Although examples of the present disclosure have been described in detail, it should be understood that the various changes, substitutions, and alterations could be made hereto without departing from the spirit and scope of the present disclosure.

What is claimed is:

1. A method, comprising:
receiving, at a receiver, a signal comprising a symbol;
performing, at the receiver in a first stage, a first operation to determine one or more most significant bits of the symbol; and
outputting, at the receiver, the one or more most significant bits when the one or more most significant bits falls within a hard resolution region.

2. The method of claim 1, further comprising:
converting, at the receiver in a second stage, one or more least significant bits when the one or more most significant bits falls within a full resolution region; and
combining, at the receiver, the one or more least significant bits with the one or more most significant bits when the one or more most significant bits falls within a full resolution region.

3. The method of claim 1, further comprising:
stopping, at the receiver, a conversion of one or more least significant bits in one or more adjacent slices.

4. The method of claim 1, further comprising:
performing, at the receiver, an analog delay before converting one or more least significant bits.

5. The method of claim 1, further comprising using a prediction engine to compute a first conversion result.

6. The method of claim 5, further comprising using the prediction engine to make a second conversion decision based on the first conversion result.

7. The method of claim 1, wherein the first operation is a first equalization operation that uses a feed forward equalizer (FFE).

8. A system for deferred resolution, comprising:
an analog to digital converter (ADC) stage operable to receive input, convert one or more most significant bits from the input, and generate an ADC residue from the input;
an equalizer comprising a plurality of taps, wherein the equalizer is operable to receive the one or more most significant bits after conversion; and
a final ADC stage operable to provide one or more least significant bits to the equalizer when full resolution is selected.

9. The system of claim 8, further comprising:
an analog delay stage operable to delay a conversion of the one or more least significant bits.

10. The system of claim 8, wherein the equalizer is operable to equalize the one or more least significant bits when full resolution is selected.

11. The system of claim 8, wherein the equalizer is operable to stop a conversion of one or more least significant bits in one or more adjacent slices.

12. The system of claim 8, further comprising a deferred resolution prediction engine.

13. The system of claim 12, wherein the deferred resolution prediction engine is operable to determine a second conversion decision based on a first conversion result.

14. The system of claim 8, further comprising one or more processors operable to determine one or more thresholds for full resolution.

15. The system of claim 8, wherein the equalizer is a feed forward equalizer.

16. An analog-to-digital converter (ADC), comprising:
a first stage operable to convert, at the ADC, one or more most significant bits; and
a second stage operable to delay, at the ADC, conversion of one or more least significant bits, and
wherein the ADC is operable to convert, in a second stage, one or more least significant bits when the one or more most significant bits falls within a full resolution region.

17. The ADC of claim 16, further comprising:
a prediction engine operable to compute a conversion decision for the one or more least significant bits.

18. The ADC of claim 16, further comprising:
a prediction engine operable to compute a second conversion decision based on a first conversion result.

19. The ADC of claim 16, wherein the ADC is operable to stop a conversion of the one or more least significant bits in one or more adjacent slices.

20. The ADC of claim 16, wherein the ADC is operable to determine one or more thresholds for full resolution.
